(19) United States
(12) Patent Application Publication
(10) Pub. No.: US 2010/0252434 A1
(43) Pub. Date: Oct. 7, 2010

(54) Bio-Sensor Using Gated Electrokinetic Transport

(75) Inventor: Subrata Roy, Gainesville, FL (US)

Correspondence Address: SALIWANCHIK LLOYD & SALIWANCHIK;A PROFESSIONAL ASSOCIATION, PO Box 142950, GAINESVILLE, FL, 32614, US

(73) Assignee: University of Florida Research Foundation, Inc., Gainesville, FL (US)

(21) Appl. No.: 12/675,813

(22) PCT Filed: Aug. 28, 2008
(86) PCT No.: PCT/US08/74637

§ 371 Date: Mar. 1, 2010

Related U.S. Application Data
(60) Provisional application No. 60/968,340, filed on Aug. 28, 2007.

(51) Int. Cl. G01N 27/26; F28F 7/00; H01L 29/775

(52) U.S. Cl. 204/456; 204/606; 165/185; 257/9; 257/E29.245; 977/938

(57) ABSTRACT

Embodiments of the present invention provide a method and apparatus for selective electrokinetic separation. In an embodiment, a local gate electric field is applied to a voltage-gated nanochannel filled with an aqueous solution. Additionally, a surface charge may be present on the walls of the nanochannel. This local gate electric field shows a selective quenching feature of ionic density and behaves as a potential shield against selective charge from entering the nanochannel while facilitating transport of the opposite charge. Embodiments of the subject method can also be used to enhance osmotic diffusion of selective electrolytes through biological cells. Specific embodiments can be useful as a biosensor since most biological cells contain an aqueous solution. A surface charge and local gate electric field can be applied to a biological cell to selectively separate molecules, such as proteins or ions. Embodiments of the subject method can be used in conjunction with a field effect transistor to provide more efficient electrokinetic transport. In an embodiment, the subject invention provides an improved field effect transistor. By applying a surface charge to the walls of a nanochannel in a semiconductor material, the electric field of the transistor gives more selective separation of charged carriers.

### CROSS-REFERENCE TO RELATED APPLICATION

The present application claims the benefit of U.S. Provisional Application Ser. No. 60/968,340, filed Aug. 28, 2007, which is hereby incorporated by reference herein in its entirety, including any figures, tables, or drawings.

### BACKGROUND OF THE INVENTION

Electrokinetics is the science of the motion of ionized particles in a fluid and their interactions with electric fields and the surrounding fluid. Electrokinetic processes include electrophoresis caused by the motion of charged particles through a stationary solution [3, 4] and electroosmosis where a net aqueous solution mass transfers.

The ability to move ions of a particular charge while repelling ions of the opposite charge can be very useful. A biological cell is ion-penetrable and typically carries a distributed negative charge on its surface. The mechanism of selective ion transport is important in many applications, including biological systems, fuel cells, and microelectronics. [1, 2]

When walls of a nanochannel carrying a distributed negative charge on its surface, such as in a neuron or other biological cell, come in contact with an aqueous solution, the positive ions are attracted to the surface while negative ions are repelled. This creates a selective gradient of ions forming a double layer called Stern or diffuse layer.

One existing practical application for electrokinetics is gel electrophoresis. Gel electrophoresis is often used to match up DNA from different sources. An electric field is applied to a gel containing DNA, RNA, or other proteins to force the molecules through the gel. Molecules are separated based on their size and electric charge.

Field effect transistors also make use of electrokinetics. A field effect transistor relies on an electric field to control the shape and conductivity of a channel in a semiconductor material.

A method providing more efficient and selective electrokinetic transport would be very useful in the art.

### BRIEF SUMMARY

Embodiments of the present invention provide a method and apparatus for selective electrokinetic separation. In an embodiment, a local gate electric field is applied to a voltage-gated nanochannel filled with an aqueous solution. Additionally, a surface charge may be present on the walls of the nanochannel. This local gate electric field shows a selective quenching feature of ionic density and behaves as a potential shield against selective charge from entering the nanochannel while facilitating transport of the opposite charge.

Embodiments of the subject method can also be used to enhance osmotic diffusion of selective electrolytes through biological cells. Specific embodiments can be useful as a biosensor since most biological cells contain an aqueous solution. Further embodiments can be used as a biofilter, allowing certain biological cells to pass and hindering or preventing the passage of certain other biological cells. A surface charge and local gate electric field can be applied to a biological cell to selectively separate molecules, such as proteins or ions.

Embodiments of the subject method can be used in conjunction with a field effect transistor to provide more efficient electrokinetic transport. In an embodiment, the subject invention provides an improved field effect transistor. By applying a surface charge to the walls of a nanochannel in a semiconductor material, the electric field of the transistor gives more selective separation of charged carriers.

Additional embodiments relate to a surface having microchannels that have surface charge and/or a voltage biased across the microchannels so as to induce and/or enhance fluid flow in the microchannels in order to cool the surface.

### BRIEF DESCRIPTION OF THE DRAWINGS

FIG. 1A shows a schematic picture of a neuron and a computational grid for the area of the neuron that is highlighted with a dotted line.

FIG. 1B shows distribution of potential and species concentration along the centerline y=5 for surface charge σ=σ_{g}=−1 mC/m².

FIG. 1C shows distribution of ion current along the centerline y=5 for surface charge σ=σ_{g}=−1 mC/m².

FIG. 1D shows distribution of potential and species concentration along the midsection at x=35 for σ=−1 mC/m².

FIG. 1E shows the selective response of an applied gate electric field at σ=−1 mC/m² and σ_{g}=0 mC/m².

FIG. 2A shows density and potential distribution along the line of symmetry for surface charge density of σ=σ_{g}=−2 mC/m².

FIG. 2B shows density and potential distribution along the line of symmetry for surface charge density of σ=σ_{g}=−5 mC/m².

FIG. 2C shows density and potential distribution along the line of symmetry for surface charge density of σ=−2 mC/m² and σ_{g}=mC/m².

FIG. 2D shows density and potential distribution along the line of symmetry for surface charge density of σ=−2 mC/m² and σ_{g}=0 mC/m².

FIG. 2E shows the effect of gate charge on ionic current distribution for surface charge density of σ=−2 mC/m² and σ_{g}=−1 mC/m².

FIG. 3A shows a plot of velocity components in the streamwise (u—solid line) and crosswise (v—dotted line) for a quiescent flow in the absence of an external pressure gradient for Δφ=1 volt and σ=σ_{g}=−1 mC/m².

FIG. 3B shows a plot of velocity components in the streamwise (u—solid line) and crosswise (v—dotted line) for a quiescent flow in the absence of an external pressure gradient for Δφ=1 volt, σ=−1 mC/m², and σ_{g}=0 mC/m².

FIG. 3C shows a plot of velocity components in the streamwise (u—solid line) and crosswise (v—dotted line) for a quiescent flow in the absence of an external pressure gradient for Δφ=1 volt and σ=σ_{g}=−2 mC/m².

FIG. 3D shows a plot of velocity components in the streamwise (u—solid line) and crosswise (v—dotted line) for a quiescent flow in the absence of an external pressure gradient for Δφ=1 volt, σ=−2 mC/m², and σ_{g}=0 mC/m².

FIG. 3E shows a plot of velocity components in the streamwise (u—solid line) and crosswise (v—dotted line) for a quiescent flow in the absence of an external pressure gradient for Δφ=3 volts and σ=σ_{g}=−2 mC/m².

FIG. 3F shows a plot of velocity components in the streamwise (u—solid line) and crosswise (v—dotted line) for a quiescent flow in the absence of an external pressure gradient for Δφ=3 volts, σ=−2 mC/m², and σ_{g}=−1 mC/m².

FIG. 4A shows the average species concentration and current in the channel for varying surface charges.

FIG. 4B shows a prediction of the variation of average change in species density and current for varying surface charge differences at the gate, where Δσ=σ_{g}−σ.

### DETAILED DISCLOSURE

Embodiments of the present invention provide a method and apparatus for selective electrokinetic separation. Specific embodiments of the invention can be used in conjunction with a biosensor, a biofilter, or a field effect transistor. In an embodiment, a local gate electric field is applied to a voltage-gated nanochannel filled with an aqueous solution. Specific embodiments can operate under electrophoretic and/or electroosmotic conditions. Additionally, a surface charge may be present on the walls of the nanochannel. This local gate electric field shows a selective quenching feature of ionic density and behaves as a potential shield against selective charge from entering the nanochannel while facilitating transport of the opposite charge. The local voltage difference can be applied using any conventional means for applying a voltage difference which are known in the art. Furthermore, the sensitivity of separation of ions at low voltage can be significantly improved over previous electrokinetic methods. In an embodiment, a voltage gated nanochannel filled with an aqueous solution of KCl under electrophoretic and/electroosmotic conditions, with a surface charge of −1, −2, or −5 mC/m², can be used for charge transport. The application of local gate electric field can provide a selective quenching feature for ionic density and can behave as a potential shield against selective charge from entering the channel, while facilitating transport of the other charge.

In embodiments of the present invention, a global electric field can also be applied to provide more efficient separation of ions. Any conventional means known in the art for applying an electric field may be used.

The method and apparatus of the present invention are useful as a biosensor since most biological cells contain an aqueous solution. A surface charge and local gate electric field is applied to a biological cell to selectively separate molecules, such as proteins or ions.

The surface charge can be adjusted to alter the effects on ion transport of electrophoresis and electroosmosis. As the surface charge increases, the effect of electroosmosis increases. The ratio of electroosmotic to electrophoretic current can be increased by increasing the surface charge density. Altering the surface charge leads to improved selectivity and efficiency in separating molecules. The channel gate potential can also be varied to selectively control electrokinetic transport of ions. The selective transport of gate potential applied through a biased surface charge in a nanochannel can be useful in a variety of areas. The transport control mechanism can also be sensitive to the potential difference across the nanochannel. The mechanism of selective ion transport can be incorporated into applications such as, but not limited to, biological systems, fuel cells, and microelectronics. For example, blood can be cleaned by selectively removing certain ions, such as potassium, chlorine, and/or sodium ions. Cleaning blood in this way can be shear free. In another embodiment, renal and/or hemo dialysis can be accomplished by selectively removing certain proteins or other charged particles such as potassium, calcium, and urea.

The subject invention also provides an improved field effect transistor. By applying a surface charge to the walls of a nanochannel in a semiconductor material, the electric field of the transistor gives more selective separation of charged carriers.

Additional embodiments relate to a surface having microchannels that have surface charge and/or a voltage biased across the microchannels so as to induce and/or enhance fluid flow in the microchannels in order to cool the surface. The microchannels can be etched into the surface or otherwise formed. The sides, or other portions of the microchannels and/or adjacent portions of the surface can have coatings of electrically conductive materials to function as electrodes. The electrodes can be addressable such that a voltage can be applied to the electrodes. The microchannels can be parallel and/or cross-hatched, or have other patterns on the surface. In specific embodiments the microchannels can be between 1 μm and 1 mm wide, and in a preferred embodiment between 10 μm and 50 nm wide. The microchannels can induce heat transfer by increasing surface area of the surface and by increasing the convection coefficient. By inducing flow of a fluid in the microchannel the surface can be cooled, or heated if a heated fluid is used.

It is important to note that, as used herein, the term “nanochannel” refers to any small scale channel through which an aqueous solution can flow, and includes biological cells. Also, as used herein, the term “wall” or “walls” of a nanochannel refers to the boundaries of such a nanochannel and includes the boundary of a biological cell. Although methods and materials similar or equivalent to those described herein can be used in the practice or testing of embodiments of the present invention, suitable methods and materials are described below.

### Example 1

### A Voltage-Gated KCl Aqueous Solution Nanochannel

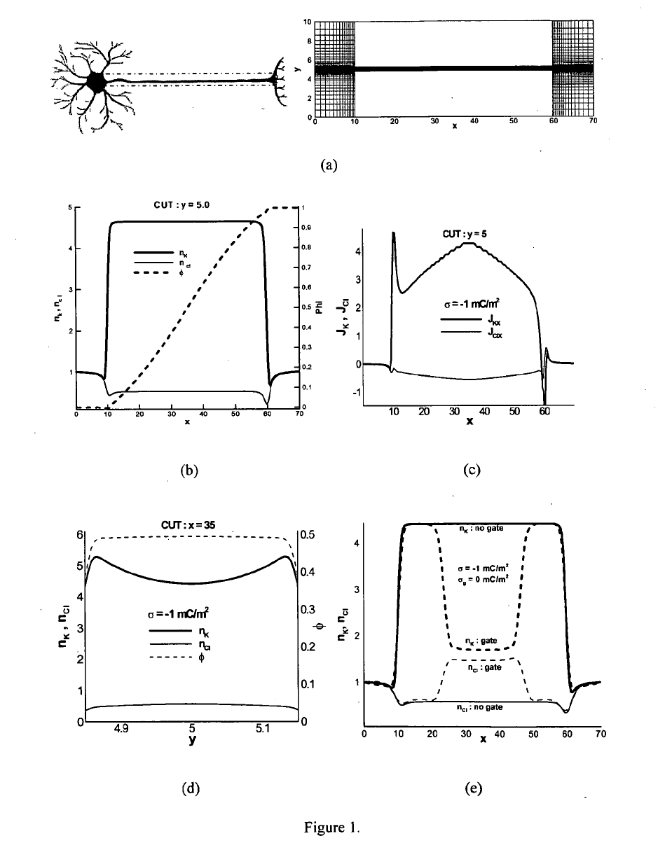

Parametric variations of applied global and local electric field and potential differences were applied along the surface and the gate region in simulating the controlled ionic species transport through a nano-fluidic channel. The channel shown in FIG. 1a is 5 μm long and is filled with a 10⁻⁴ M (˜6.022×10²² m⁻³) KCl aqueous solution. K⁺ cation and Cl⁻ halogen are abundant in biological cells. Two reservoirs, each 1 μm×1 μm, were attached to either side of the channel. The channel was 30 nm in height. The walls of the channel were negatively biased.

For this example, the Debye length of the ions was in the range of 40 nm to 500 nm for ion densities of 10⁻² to 10⁻⁴ M within the channel, respectively. When the height of the channel is smaller than the Debye length, the ionic current due to electrophoresis is dominant. For a given channel, as the charge density of the wall surface increases, ionic current due to electroosmosis also becomes dominant and hence cannot be neglected. The selective transport through the electrical double layer can be achieved. A separation modality can be utilized for nanoscale electrophoretic separations. Based on Nernst-Planck approximation, the flux Ja due to ionic species is represented in terms of its following gradients.

$${J}_{α} = - {D}_{α} ( ∇ {n}_{α} + sgn ( α ) \frac{{n}_{α}}{kT} ∇ φ ) , for α = {K}^{+} or {Cl}^{-} \qquad ( 1 )$$

where, n is the number density, f is the potential, D is diffusion coefficient of the ionic species, and T is temperature in K. The Poisson equation below represents charge difference as a function of potential in the system.

∇·(ε∇φ)=−q (2)

where, the space charge

$$q = {\sum }_{α}^{N} {ez}_{α} {n}_{α}$$

is a function of ionicity z of N species with concentration n, and e is the elementary charge. For KCl solution, q=e(n_{K}_{⁺}−n_{Cl}_{^{−}}). The system of equations is closed using the following continuity equation below.

∇·J_{α}=0 (3)

The temperature (T) of the ionic species is cold at 298 K. Permittivity of KCl aqueous solution (e) is 7×10⁻¹⁰ C²/N·m², and the dynamic viscosity (μ) is 10⁻³ N·s/m². For steady, low Reynolds number incompressible flow with velocity u (u,v), the Navier-Stokes equation in the absence of external pressure gradient gets modified into

∇·(μ∇u)−e(n_{K}_{⁺}−n_{Cl}_{^{−}})∇φ=0 (4)

The system of equations (1)-(4) is normalized using the following equivalent forms: (x,y)=(x,y)/d, n_{K}=n_{K}/n₀, n_{Cl}=n_{Cl}/n₀, and f=ef/Tₑ. Here, d is a reference length which represents the physical geometry, n₀=6.04×10²² m⁻³ is a reference density, which is here taken as the bulk density, and Tₑ (=1 eV) is a reference temperature. The hydrodynamic equations of K⁺ and Cl⁻, along with the electrostatic field equation, are solved numerically using a self-consistent multiscale subgrid embedded finite-element algorithm. [6,7] The bi-quadratic spatial approximation is at least third order accurate and a fully implicit Euler temporal relaxation is utilized to reach the steady asymptote. The nonlinear Newton-Raphson scheme, along with a Generalized Minimum Residual solver, is employed to solve the matrix to handle the sparseness of the resulting stiffness matrix. For a typical run, single iteration takes about 9 seconds, which involves both assembly and solver time. The solution is assumed to have converged when the L₂ norm of all solution variables and residual are below a chosen convergence criterion e, chosen as 10⁻³ for f and 10⁻² for n_{K}_{⁺} and n_{Cl}_{^{−}}. A subgrid embedded optimally diffusive perturbation function is used based on local cell velocity and cell size. This ensures a minimum dispersion error and a node-wise monotone solution.

The boundary conditions on the various edges of the model are summarized in Table 1. In the reservoir, all edges are fixed as Dirichlet conditions based on the bulk density and fixed reservoir potential. Along the walls of the nanochannel, zero normal current through the wall is ensured. This requires that the gradient of ionic charge density be a function of potential gradient based on Equations (1) and (2). For the potential equation, the flux is specified based on the charge density s on the surface of the nanochannel wall. A gate surface charge density of s_{g} is applied along the walls in the midsection of the nanochannel. For the velocity equation (4), no-slip conditions are imposed at the wall of the nanochannel. The ζ-potential at the electrolyte substrate interface is controlled through specification of the electric field.

TABLE 1
Boundary Conditions

| | Positive ion | Negative ion | |
|---|---|---|---|
| Edge | density | density | Potential |
| All boundary edges | Bulk | Bulk | 0 |
| of left reservoir | concentration | concentration | |
| All boundary edges | Bulk | Bulk | 1 or 3 |
| of right reservoir | concentration | concentration | |
| Nano-channel walls (s = surface charge density) | $∇ {n}_{K} = - \frac{{en}_{K}}{kT} ∇ φ$ | $∇ {n}_{Cl} = - \frac{{en}_{Cl}}{kT} ∇ φ$ | $∇ φ = - \frac{σ}{{ɛ}_{0}}$ |

FIG. 1A shows the computational grid consisting of 26×16 non-uniform bi-quadratic elements in the nanochannel. Each reservoir is packed with 7×40 bi-quadratic non-uniform elements. The maximum aspect ratio is limited to about 248 in this case, which occurs near the center of the channel. FIG. 1B shows a representative distribution of species concentration of cations and halogens along the streamwise centerline of the nanochannel. The wall and gate are maintained at the same negative charge of s=s_{g}−1×10⁻³ C/m² with allowed potential drop of 1 volt. The potential remains constant at both reservoirs and gradually increasing slope in the channel. The corresponding electric field is symmetric with its peak magnitude at the middle of the channel and abruptly vanishing inside both reservoirs. K⁺ and Cl⁻ ionic current distributions are plotted in FIG. 1C and reflect large variations at the channel entrance and exit corresponding to the electric field. FIG. 1D shows potential and density profiles along crosswise centerline of the channel. Large drops of potential and ionic current change near the walls signify sheath region. The density dip in the middle of the channel increases linearly as the magnitude of the surface charge increases (not shown).

When a gate potential is applied setting the surface charge density of s_{g}=0, the difference in densities is evident. FIG. 1e shows the comparison of normalized positive (K⁺) and negative (Cl⁻) ion number densities at steady state for surface charge of s=−1 mC/m² without (s_{g}=s) and with a gate potential s_{g}=0 applied on the channel wall. The cation density drops nearly 50% while the halogen density increases by 150%. This selective response of applied gate electric field is shown in the reduction of cation and increase in halogen at s=−1 mC/m² and s_{g}=0.

Assuming the bulk flow is free of net charge, the Debye-Huckel approximation of a solution at a charged plane at a potential ζ in an electrolyte is φ=ζexp(−y/λ_{D}), where y is distance normal to the wall and the Debye length λ_{D}=(kT_{B}/4pn₀e²). The potential shielding by the free charges in solution is limited within a distance of the order of λ_{D} or a few microns. This approximation falls far short when a gate voltage is applied.

### Example 2

### A Voltage-Gated KCl Aqueous Solution Nanochannel at Varying Surface and Gate Charges

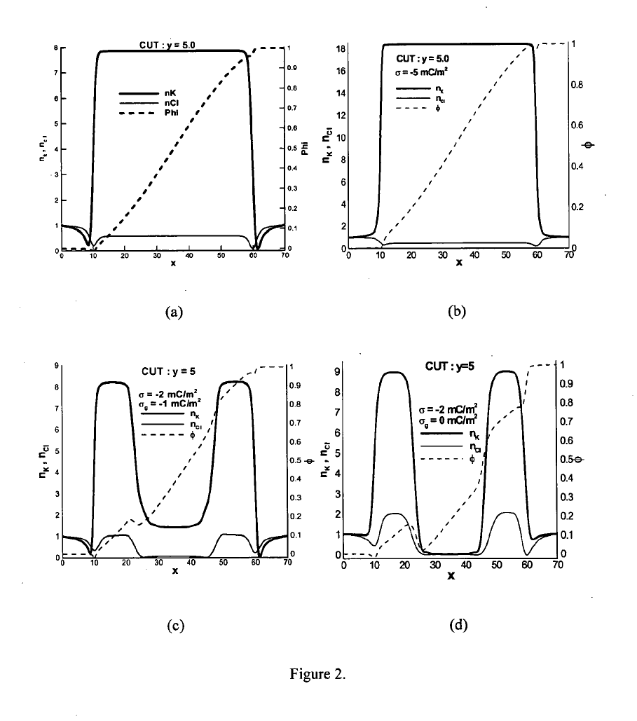

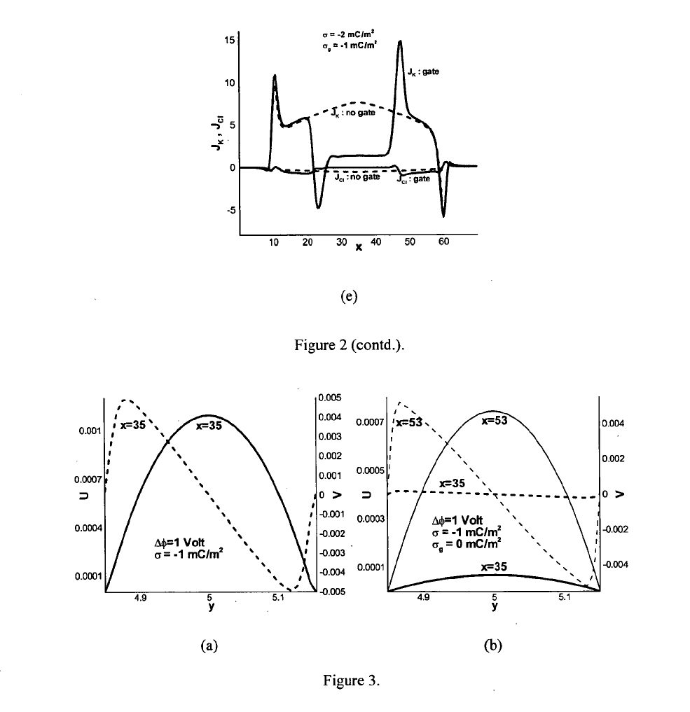

As we change the surface charge to s=−2 mC/m², cation transport nearly doubles for the same potential drop of 1 volt, while the halogen reduces by half as shown in FIG. 2A. The K⁺ concentration linearly increases (from 4.5 at s=−1 mC/m² to 18 at s=−5 mC/m²), and Cl⁻ concentration decreases even further in FIG. 2B as the surface charge increases. The channel becomes an essentially unipolar solution of potassium cations as a gate charge of s_{g}=−1 mC/m² in FIGS. 2C and s_{g}=0 in FIG. 2D is applied along with s=−2 mC/m². This is suitable for synthesis of cations in a bio-transistor. The effect of gate charge is evident also in the ion current plotted in FIG. 2E. The change is largely noticeable in a potassium ion current with an electrical double layer identifying electroosmotic current characteristic.

### Example 3

### Interpreting the Species Transport Velocity Components for a KCl Aqueous Solution Nanochannel

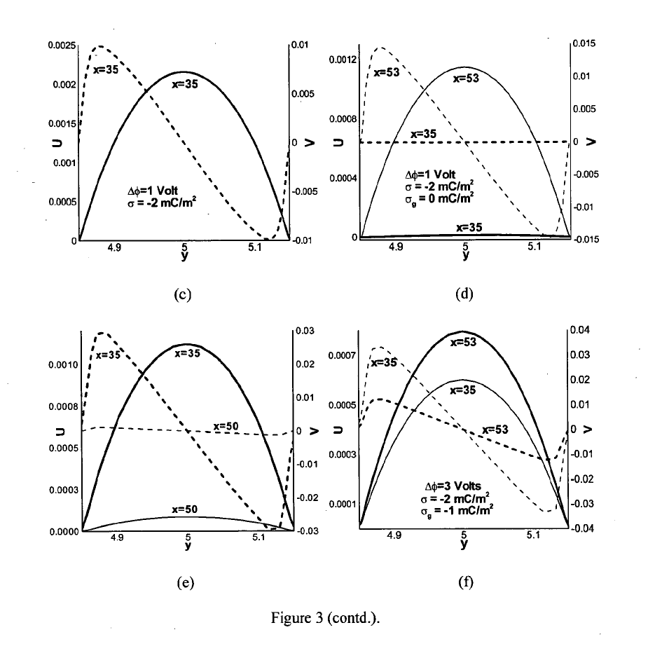

The computed species transport velocity components are shown in FIG. 3 for a range of potential difference and gate charges at two different cross-sections of the channel. The non-dimensional location of x=35 is the middle of our nanochannel, and x=53 is slightly downstream of the gate. FIGS. 3A-3D plot the effect of surface and gate charge for a potential drop of 1 volt. Clearly, application of gate charge nearly stops the flow while outside the gate the velocity slightly increases creating a standing wave. As we increase the voltage of the right reservoir from 1 to 3 volts in FIGS. 3E-3F, the gate charge of −1×10⁻³ C/m² does not sufficiently dampen the velocity to a complete halt. The velocity components in the gate region are barely 20% less than that of the outside. This signifies the subtle nature of voltage control required for such synthesis devices.

### Example 4

### Prediction of Average Species Concentration and Current in a KCl Aqueous Solution Nanochannel at Varying Surface Charges

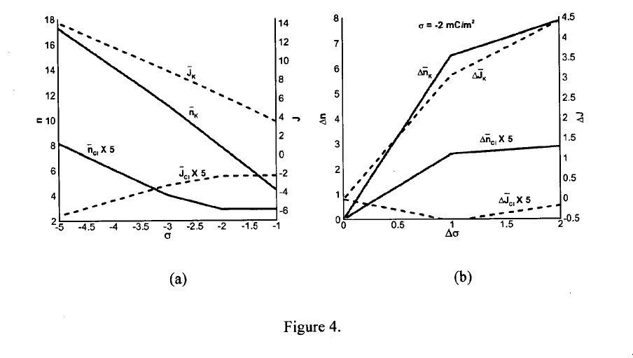

FIGS. 4A and 4B predict the n-s and J-s characteristics. These curves provide useful calibration information for a bio-sensor to be utilized for synthesis of selected species. For example, the extent of ion accumulation increases almost linearly with applied external field. However, the ion re-distribution for a change in charge across channel and gate is not linear indicating a need for optimization.

All patents, patent applications, provisional applications, and publications referred to or cited herein are incorporated by reference in their entirety, including all Figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

It is to be understood that while the invention has been described in conjunction with the detailed description and attached figures, the foregoing description is intended to illustrate and not limit the scope of the invention, which is defined by the scope of the appended claims. Other aspects, advantages, and modifications are within the scope of the following claims.

### REFERENCES

1). Ghosal, S., Annual Review of Fluid Mechanics, 38, 309 (2006).
2). Daiguji, H., Yang, P., and Majumdar, A., Nano Letters, 4, 137 (2004).
3). Gouaux, E. and MacKinnon, R., Science, 310, 1461 (2005).
4). Kagan, C. R, Mitzi, D. B., and Dimitrakopoulos, C. D., Science, 286, 945 (1999).
5). Qiao, R. and Aluru, N. R, Journal of Chemical Physics, 118, 4692 (2003).
6). Roy, S., Applied Physics Letters, 86, 101502 (2005).
7). Cooper, S. M., Cruden, B., Meyyappan, M., Raju, R., and Roy, S., Nano Letters, 4, 377 (2004).

1. A biofilter, comprising:
a nanochannel, wherein the nanochannel has walls, wherein the walls have a surface charge;
an aqueous solution comprising biological cells; and
a means for applying a voltage difference across the nanochannel, wherein the voltage difference applied across the nanochannel selectively affects the transport properties of the biological cells in the aqueous solution, wherein the means for applying a voltage difference across the nanochannel allows operation of the biofilter in an electroosmosis region and in an electrophoresis region.

2. The biofilter according to claim 1, further comprising a means for applying a global electric field to the nanochannel.

3. The biofilter according to claim 1, wherein the surface charge is negative.

4. The biofilter according to claim 3, wherein the surface charge is from about −1 mC/m² to about −5 mC/m².

5. The biofilter according to claim 4, wherein the surface charge is about −1 mC/m².

6. The biofilter according to claim 4, wherein the surface charge is about −2 mC/m².

7. The biofilter according to claim 4, wherein the surface charge is about −5 mC/m².

8. The biofilter according to claim 1, wherein the biological cells comprise positive ions and negative ions, wherein a voltage difference applied across the nanochannel separates the positive ions from negative ions in the aqueous solution.

9. A method for electrokinetic transport, comprising:
introducing an aqueous solution comprising biological cells into a nanochannel;
applying a voltage difference across a nanochannel, wherein the nanochannel has walls, wherein the walls have a surface charge, wherein applying a voltage difference across the nanochannel selectively affects the transport properties of the biological cells in the aqueous solution.

10. The method according to claim 9, wherein the aqueous solution comprises positive ions and negative ions, wherein applying a voltage difference across the nanochannel separates the positive ions from the negative ions in the aqueous solution.

11. The method according to claim 9, further comprising applying a global electric field to the nanochannel.

12. The method according to claim 9, wherein the surface charge is negative.

13. The method according to claim 12, wherein the surface charge is from about −1 mC/m² to about −5 mC/m².

14. The method according to claim 13, wherein the surface charge is about −1 mC/m².

15. The method according to claim 13, wherein the surface charge is about −2 mC/m².

16. The method according to claim 13, wherein the surface charge is about −5 mC/m².

17. A field effect transistor, comprising:
a nanochannel; and
a means for applying a voltage difference to the nanochannel, wherein the nanochannel has walls, wherein the walls have a surface charge.

18. The field effect transistor according to claim 17, further comprising a means for applying a global electric field to the nanochannel.

19. The field effect transistor according to claim 17, wherein the surface charge is negative.

20. The biofilter according to claim 1, wherein the transport properties comprise mobility.

21. The method of heat transfer between a fluid and a surface, comprising:
providing at least one microchannel on a surface;
introducing a fluid into the at least one microchannel, wherein the fluid comprises charged particles;
applying a bias voltage across the at least one microchannel so as to induce the fluid to flow in the at least one microchannel, wherein heat transfer occurs between the fluid and the surface.

22. The method according to claim 21, wherein the at least one microchannel has a width between 1 μm and 1 mm.

23. The method according to claim 21, wherein the at least one microchannel has a width between 10 μm and 50 μm.

24. The method according to claim 21, wherein heat is transferred from the surface to the fluid.

25. The method according to claim 21, wherein heat is transferred from the fluid to the surface.

26. The method according to claim 21, wherein the bias voltage is applied across the at least one microchannel by applying the bias voltage across electrodes positioned in the at least one microchannel.

27. The biofilter according to claim 1, wherein the means for applying a voltage difference across the nanochannel comprises coatings on at least a portion of the walls of the nanochannel, wherein the coatings function as electrodes, wherein applying the voltage difference across two or more of the coatings applies the voltage difference across the nanochannel.

28. The method according to claim 9, wherein applying a voltage difference across the nanochannel comprises applying the voltage difference across two or more coatings on at least a portion of the walls of the nanochannel, wherein the two or more coatings function as electrodes.
